(19) United States
(12) Patent Application Publication
(10) Pub. No.: US 2026/0122876 A1
(43) Pub. Date: Apr. 30, 2026

(54) SEMICONDUCTOR DEVICE AND MANUFACTURING METHOD THEREOF

(71) Applicant: Yangtze Memory Technologies Co., Ltd., Wuhan (CN)

(72) Inventors: Wulin ZHANG, Wuhan (CN); Sen YAO, Wuhan (CN); Si QIAO, Wuhan (CN); Xuhui HU, Wuhan (CN); Ke ZHANG, Wuhan (CN); Yulin XING, Wuhan (CN); Zhi DENG, Wuhan (CN)

(21) Appl. No.: 19/222,810

(22) Filed: May 29, 2025

(30) Foreign Application Priority Data
Oct. 28, 2024 (CN) 202411517285.6

(51) Int. Cl. H10B 12/00; G11C 5/10; H10D 1/68

(52) U.S. Cl. CPC H10B 12/315; G11C 5/10; H10B 12/0335; H10B 12/318; H10D 1/716; H10B 12/50

(57) ABSTRACT

Examples of the present disclosure provide a semiconductor device and a manufacturing method thereof. The semiconductor device includes a semiconductor body, a capacitor, and a first connection structure. The semiconductor body extends along a first direction. The capacitor is located on a side of the semiconductor body in the first direction. The first connection structure is located between the semiconductor body and the capacitor, and includes a first end and a second end arranged in the first direction. The first end is connected to the capacitor, and a size of the first end in a second direction is smaller than a size of the second end in the second direction.

### CROSS-REFERENCE TO RELATED APPLICATIONS

This application claims priority to Chinese Patent Application No. 202411517285.6, filed on Oct. 28, 2024, which is hereby incorporated by reference in its entirety.

### TECHNICAL FIELD

The present disclosure relates to the field of semiconductor technology, and in particular, to a semiconductor device and a manufacturing method of the semiconductor device.

### BACKGROUND

The semiconductor device may be applied to a memory, such as a dynamic random access memory (DRAM). DRAM is widely applied to memories of electronic devices such as computers and mobile phones due to its simple structure, large capacity, high density, low power consumption, high speed and the like.

It is desirable for the semiconductor device to have better electrical performance, higher yield, and simpler manufacturing process.

### SUMMARY

In a first aspect, some examples of the present disclosure provide a semiconductor device. The semiconductor device comprises a semiconductor body, a capacitor, and a first connection structure. The semiconductor body extends along a first direction. The capacitor is located on a side of the semiconductor body in the first direction. The first connection structure is located between the semiconductor body and the capacitor and comprises a first end and a second end arranged in the first direction, wherein the first end is connected to the capacitor, and a size of the first end in a second direction is smaller than a size of the second end in the second direction.

In an implementation, the first connection structure comprises a body portion and an adhesive layer. The body portion has a first end and a third end opposite to the first end in the first direction. The adhesive layer covers the third end and part of a side surface of the body portion.

In an implementation, a size of the first end in the second direction is smaller than a size of the third end in the second direction.

In an implementation, a material of the body portion comprises a metal.

In an implementation, in the first direction, an end of the adhesive layer away from the semiconductor body is located on a side of the first end away from the capacitor.

In an implementation, the capacitor comprises a first electrode extending along a first direction, the first electrode is in contact with the first end, and a spacing distance between the first electrode and an end of the adhesive layer away from the semiconductor body in the first direction is greater than zero.

In an implementation, the capacitor comprises a first electrode extending along the first direction. The semiconductor device further comprises an insulation structure. The insulation structure is located between the first electrode and the adhesive layer in the first direction.

In an implementation, a size of an end of the insulation structure close to the first electrode in the second direction is greater than a size of an end of the insulation structure close to the adhesive layer in the second direction.

In an implementation, the semiconductor device further comprises an isolation layer. The isolation layer is located between adjacent first connection structures. The insulation structure is located between the body portion and the isolation layer. For example, a material of the isolation layer comprises silicon nitride.

In an implementation, the semiconductor device further comprises an insulation layer. The insulation layer is located on a surface of the isolation layer away from the semiconductor body in the first direction, and is located between adjacent first electrodes. Materials of the insulation structure and the insulation layer are the same. For example, the materials of the insulation structure and the insulation layer comprise boron-doped silicon nitride.

In an implementation, the semiconductor device further comprises a second connection structure. The second connection structure extends along the first direction and is connected to the first connection structure and the semiconductor body. For example, a material of the second connection structure comprises a semiconductor.

In an implementation, the semiconductor device further comprises a gate structure and a first dielectric layer. The gate structure is located on at least one side of the semiconductor body in a direction intersecting the first direction. The first dielectric layer is between the gate structure and the semiconductor body.

In an implementation, the gate structure is located on a side of the semiconductor body in the second direction. The semiconductor device further comprises a conductive structure and a second dielectric layer. The conductive structure is located on a side of the semiconductor body away from the gate structure in the second direction. The second dielectric layer is between the conductive structure and the semiconductor body.

In an implementation, the capacitor further comprises an insulation dielectric layer and a second electrode. The insulation dielectric layer covers at least part of the first electrode. The second electrode covers the insulation dielectric layer.

In an implementation, the semiconductor device further comprises a peripheral circuit structure. The peripheral circuit structure is located on a side of the semiconductor body away from the capacitor in the first direction; or the peripheral circuit structure is located on a side of the capacitor away from the semiconductor body in the first direction.

In a second aspect, some examples of the present disclosure further provide another semiconductor device. The semiconductor device comprises a semiconductor body, a capacitor, a first connection structure, and an insulation structure. The semiconductor body extends along a first direction. The capacitor is located on a side of the semiconductor body in the first direction and comprises a first electrode extending along the first direction. The first connection structure extends to the first electrode along the first direction and comprises a body portion and an adhesive layer. The adhesive layer covers an end of the body portion close to the semiconductor body and part of a side surface of the body portion. The insulation structure is located between the first electrode and the adhesive layer in the first direction.

In an implementation, a size of an end of the insulation structure close to the first electrode in the second direction is greater than a size of an end of the insulation structure close to the adhesive layer in the second direction. The first direction intersects the second direction.

In an implementation, the semiconductor device further comprises an isolation layer. The isolation layer is located between adjacent first connection structures. The insulation structure is located between the body portion and the isolation layer. For example, a material of the isolation layer comprises silicon nitride.

In an implementation, the semiconductor device further comprises an insulation layer. The insulation layer is located on a surface of the isolation layer away from the semiconductor body in the first direction, and is located between adjacent first electrodes. Materials of the insulation structure and the insulation layer are the same. For example, the materials of the insulation structure and the insulation layer comprise boron-doped silicon nitride.

In an implementation, the semiconductor device further comprises a second connection structure. The second connection structure extends along the first direction and is connected to the first connection structure and the semiconductor body. For example, a material of the second connection structure comprises a semiconductor.

In a third aspect, some examples of the present disclosure provide a manufacturing method of a semiconductor device. The manufacturing method of the semiconductor device comprises: forming an isolation layer on a side of a semiconductor body in a first direction, wherein the semiconductor body extends along the first direction; forming a hole extending through the isolation layer to the semiconductor body; forming a first connection structure in the hole; etching back the first connection structure and the isolation layer to obtain a groove surrounding a part of the first connection structure away from the semiconductor body; forming an insulation structure in the groove; and forming a capacitor on a side of the first connection structure away from the semiconductor body.

In an implementation, the manufacturing method of the semiconductor device further comprises: forming an insulation layer on a surface of the isolation layer away from the semiconductor body in the first direction, wherein forming the capacitor on the side of the first connection structure away from the semiconductor body comprises: forming a first electrode extending along the first direction and through the insulation layer to the first connection structure.

In an implementation, the insulation layer and the insulation structure are formed in the same thin film deposition process.

In an implementation, the manufacturing method of the semiconductor device further comprises: forming a second connection structure at bottom of the hole, wherein a material of the second connection structure comprises a semiconductor; wherein forming the first connection structure in the hole comprises: forming the first connection structure at top of the hole.

In an implementation, forming the first connection structure at top of the hole comprises: forming an adhesive layer on a top side wall of the hole and a top surface of the second connection structure; and forming a body portion on an inner side of the adhesive layer, wherein a material of the body portion comprises a metal. Etching back the first connection structure and the isolation layer comprises: etching back the adhesive layer, the body portion and the isolation layer to obtain a groove surrounding part of the body portion away from the semiconductor body.

In an implementation, a top width of the groove is greater than a bottom width of the groove.

In an implementation, forming the first connection structure at top of the hole comprises: depositing a conductive material at top of the hole and a surface of the isolation layer away from the semiconductor body; and removing a portion of the conductive material deposited on the surface of the isolation layer away from the semiconductor body by a mechanical chemical polishing process.

According to a fourth aspect, some examples of the present disclosure provide a memory system. The memory system comprises a memory and a controller, and the memory comprises the semiconductor device according to any of the above implementations. The controller is coupled with the memory and configured to control the memory to store data.

### BRIEF DESCRIPTION OF THE DRAWINGS

Other features, objectives, and advantages of the present disclosure will become more apparent according to the detailed description of illustrative examples made with reference to the following drawings.

FIG. 1 is a schematic cross-sectional view of a semiconductor device according to an example of the present disclosure;

FIG. 2 is a schematic cross-sectional view of a first electrode, a first connection structure and an insulation structure in a semiconductor device according to an example of the present disclosure;

FIG. 3 is a schematic flowchart of a manufacturing method of a semiconductor device according to an example of the present disclosure;

FIG. 4A to FIG. 4J are schematic cross-sectional views of a semiconductor device in a manufacturing process according to an example of the present disclosure;

FIG. 5 is a schematic block diagram of a system having a memory system according to an example of the present disclosure; and

FIG. 6A and FIG. 6B are schematic block diagrams of a memory system according to an example of the present disclosure.

### DETAILED DESCRIPTION

In order to have a better understanding of the present disclosure, various aspects of the present disclosure will be described in more detail with reference to the accompanying drawings. It should be understood that these detailed descriptions are merely descriptions of implementations of the present disclosure, and are not intended to limit the scope of the present disclosure in any way. Throughout the specification, like reference numbers refer to like elements. The expression “and/or” comprises any and all combinations of one or more of the associated listed items.

It should be noted that in this specification, the expressions of the first, second, third, etc. are merely used to distinguish one feature from another, and do not represent any limitation on the feature, and in particular, do not represent any order. Thus, the first connection structure discussed in this disclosure may also be referred to as a second connection structure and vice versa without departing from the teachings of the present disclosure.

In the drawings, the thickness, size, and shape of the components have been slightly adjusted for case of illustration. The drawings are merely examples and are not drawn to scale. As used herein, the terms “approximately”, “about”, and the like are used as terms to denote an approximation, and are not used as terms of degree, and are intended to illustrate inherent deviations in measured values or calculated values to be recognized by those skilled in the art.

It should also be understood that expressions such as “comprise”, “comprising”, “having”, “include”, and/or “including”, and the like, are open and not closed expressions in this specification that indicate the presence of stated features, elements, and/or components, but do not preclude the presence of one or more other features, elements, components, and/or combinations thereof. Furthermore, when an expression such as “at least one of” appears after the list of listed features, it refers to the entire list of features rather than just referring to an individual element in the list. Furthermore, when describing implementations of the present disclosure, the term “may” is used to express “one or more implementations of the present disclosure”. Also, the term “example” is intended to refer to an example or illustration.

Unless otherwise defined, all terms (including engineering terms and scientific terms) used herein have the same meaning as those of ordinary skill in the art to which this disclosure pertains. It should also be understood that unless stated explicitly in the present disclosure, words defined in commonly used dictionaries should be interpreted as having a meaning that is consistent with their meaning in the context of the related art, and should not be interpreted in an idealized or overly formal sense.

It should be noted that, in the case of no conflict, implementations and features in the implementations of the present disclosure may be combined with each other. In addition, unless expressly defined or contradicted with context, the specific steps included in the method described in this disclosure are not necessarily limited to the recited order, but may be performed in any order or in parallel.

Furthermore, the term “connected” or “coupled”, when used in the present disclosure, may represent direct or indirect contact between the corresponding components, unless otherwise defined or otherwise derived from the context.

Hereinafter, the present disclosure will be described in detail with reference to the accompanying drawings and the examples.

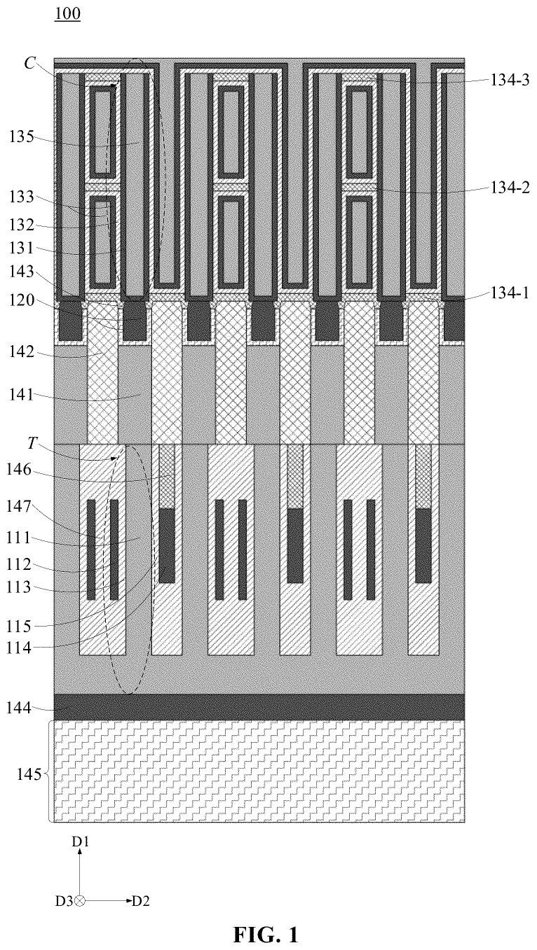

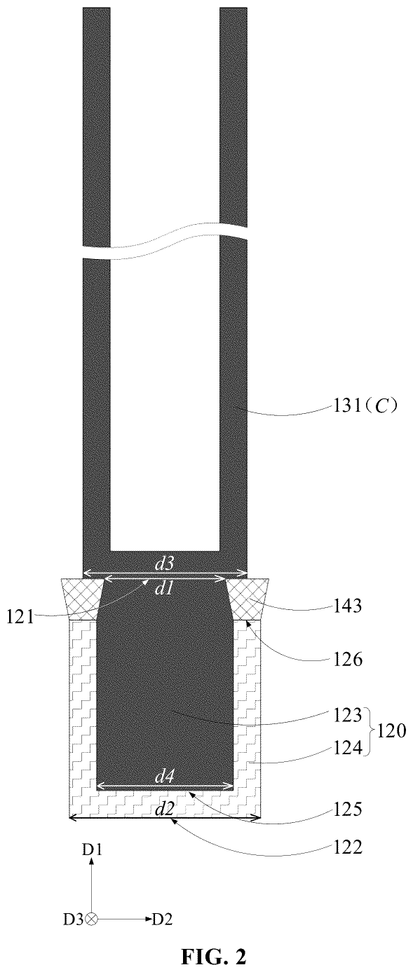

Some examples of the present disclosure provide a semiconductor device. FIG. 1 is a schematic cross-sectional view of a semiconductor device according to an example of the present disclosure. FIG. 2 is a schematic cross-sectional view of a first electrode, a first connection structure and an insulation structure in a semiconductor device according to an example of the present disclosure.

It should be noted that the D1 direction (corresponding to the first direction), the D2 direction (corresponding to the second direction), and the D3 direction (corresponding to the third direction) in the figures show the spatial relationship of the components in the semiconductor device. For example, the D1 direction may be an extension direction of the semiconductor body, and the D2 direction and the D3 direction may be two respective directions intersecting (e.g., perpendicular to) each other in a plane intersecting (e.g., perpendicular to) the extension direction. The same concept will be applied throughout the present disclosure to describe the spatial relationship of the components in the semiconductor device.

As shown in FIGS. 1 and 2, the semiconductor device 100 may comprise a semiconductor body 111, a capacitor C, and a first connection structure 120. The capacitor C may be located on a side of the semiconductor body 111 in the D1 direction. The first connection structure 120 may be located between the semiconductor body 111 and the capacitor C. The first connection structure 120 may comprise a first end 121 and a second end 122 arranged in the D1 direction. The first end 121 is connected to the capacitor C. A size d1 of the first end 121 in the D2 direction is smaller than a size d2 of the second end 122 in the D2 direction.

In some implementations, the size of the semiconductor body 111 in the D1 direction may be greater than the size of the semiconductor body 111 in the D2 direction and may be greater than the size of the semiconductor body 111 in the D3 direction, so that the semiconductor body 111 may overall extend along the D1 direction. In some implementations, the semiconductor body 111 may substantially have a column (e.g., a quadrangular prism) shape. For example, the semiconductor body 111 may serve as a channel and an active region of the transistor T.

In some implementations, the material of the semiconductor body 111 may comprise silicon, germanium, silicon germanium, silicon carbide, gallium nitride, or any other suitable semiconductor material. For example, the material of the semiconductor body 111 may be silicon (e.g., monocrystalline silicon). In some implementations, different portions of the semiconductor body 111 may have different types of dopant elements. For example, a middle portion of the semiconductor body 111 may have a P-type dopant element, and two ends of the semiconductor body 111 may have N-type dopant elements. The P-type dopant elements may comprise, but are not limited to, boron, gallium and indium. The N-type dopant elements may comprise, but are not limited to, phosphorus, arsenic and antimony.

In some implementations, the plurality of semiconductor bodies 111 may be spaced apart from each other in the D2 direction and the D3 direction. In some implementations, respective ends of a row of semiconductor bodies 111 arranged in the D2 direction are connected to each other.

In some implementations, the semiconductor device 100 may further comprise a gate structure 112. The gate structure 112 may be located on a side of the semiconductor body 111 in at least one of the D2 direction or the D3 direction. The size of the gate structure 112 in the D1 direction may be smaller than the size of the semiconductor body 111 in the D1 direction, and the two surfaces of the gate structure 112 in the D1 direction may be located between the two surfaces of the semiconductor body 111 in the D1 direction. In some implementations, the gate structure 112 may be located on one side of the semiconductor body 111 in the D2 direction. In other examples, the gate structure 112 may be located on two sides of the semiconductor body 111 opposite to each other in the D2 direction. In yet other examples, the gate structure 112 may be located on two sides of the semiconductor body 111 opposite to each other in the D2 direction and on two sides of the semiconductor body 111 opposite to each other in the D3 direction. In addition, the gate structure 112 may also extend along the D3 direction. For example, the gate structure 112 may be connected to a column of semiconductor bodies 111 arranged along the D3 direction.

In some implementations, in a case where the gate structure 112 is located on one side of the semiconductor body 111 in the D2 direction, as shown in FIG. 1, a shape of the gate structure 112 in a plane perpendicular to the D3 direction is a rectangle. The size of the rectangle in the D1 direction may be larger than its size in the D2 direction. For example, the gate structure 112 may be formed by a “back side process” or a “front side process”.

In some implementations, the material of the gate structure 112 may comprise one or more of titanium, titanium nitride, tantalum, tantalum nitride, tungsten, molybdenum, copper, aluminum, ruthenium, or any other suitable conductive material. For example, the material of the gate structure 112 may comprise tungsten.

In some implementations, the semiconductor device 100 may further comprise a first dielectric layer 113. The first dielectric layer 113 may be located between the gate structure 112 and the semiconductor body 111. The first dielectric layer 113 may be in contact with the gate structure 112 and the semiconductor body 111. The material of the first dielectric layer 113 may comprise one or more of silicon oxide, silicon nitride, silicon oxynitride, high dielectric constant material, or any other suitable insulation material. The high dielectric constant material may comprise, but is not limited to, aluminum oxide, titanium oxide, tantalum oxide, hafnium oxide, zirconium oxide, and the like. For example, the material of the first dielectric layer 113 may be silicon oxide.

The semiconductor body 111, the first dielectric layer 113, and the gate structure 112 may constitute a transistor T. Two ends of the semiconductor body 111 serve as two active regions of the transistor T respectively. For example, when the semiconductor device 100 is in an arrangement as shown in FIG. 1, the upper end of the semiconductor body 111 may be the source of the transistor T, and the lower end of the semiconductor body 111 may be the drain of the transistor T. In a case where the two ends of the semiconductor body 111 have N-type dopant elements, the transistor T may be an N-type transistor. The channel and the active region of the transistor T are integrated in the vertical direction, which helps to save the overhead of the footprint of the transistor T.

In some implementations, in a case where the gate structure 112 is on one side of the semiconductor body 111 in the D2 direction, the semiconductor device 100 may further comprise a conductive structure 114 and a second dielectric layer 115. The conductive structure 114 may be located on a side of the semiconductor body 111 away from the gate structure 112 in the D2 direction. The second dielectric layer 115 may be located between the conductive structure 114 and the semiconductor body 111. For example, a size of the conductive structure 114 in the D1 direction may be smaller than a size of the gate structure 112 in the D1 direction, and two surfaces of the conductive structure 114 in the D1 direction may be located between two surfaces of the gate structure 112 in the D1 direction. In other words, when the semiconductor device 100 is in an arrangement as shown in FIG. 1, the upper surface of the conductive structure 114 is lower than the upper surface of the gate structure 112, and the lower surface of the conductive structure 114 is higher than the lower surface of the gate structure 112. Further, the conductive structure 114 may extend along the D3 direction. The second dielectric layer 115 may be in contact with the conductive structure 114 and the semiconductor body 111. Alternatively, the second dielectric layer 115 may extend along the D1 direction and cover a surface of the semiconductor body 111 not corresponding to the conductive structure 114.

In some implementations, the material of the conductive structure 114 may comprise one or more of titanium, titanium nitride, tantalum, tantalum nitride, tungsten, molybdenum, copper, aluminum, ruthenium, or any other suitable conductive material. The material of the second dielectric layer 115 may comprise one or more of silicon oxide, silicon nitride, silicon oxynitride, high dielectric constant material, or any other suitable insulation material. The high dielectric constant material may comprise, but is not limited to, aluminum oxide, titanium oxide, tantalum oxide, hafnium oxide, zirconium oxide, and the like. For example, the material of the conductive structure 114 may be titanium nitride. The material of the second dielectric layer 115 may be silicon oxide.

During operation of the semiconductor device 100, the conductive structure 114 may have a shielding function, thereby improving mutual interference between adjacent transistors T. For example, during operation of the semiconductor device 100, the conductive structure 114 may be configured to apply a ground voltage or a negative voltage. The second dielectric layer 115 may serve to electrically isolate the conductive structure 114 and the semiconductor body 111.

In other implementations, the conductive structure 114 may be replaced by an insulation material structure (not shown). For example, air gaps may be provided in the insulation material structure. To a certain extent, the insulation material structure with air gaps can also provide a shielding effect.

In some implementations, the semiconductor device 100 may further comprise a first isolation structure 146. The first isolation structure 146 and the conductive structure 114 may be disposed on the same side in the D2 direction with respect to the semiconductor body 111. The first isolation structure 146 may also be located on a side (e.g., a surface) of the conductive structure 114 in the D1 direction. For example, the first isolation structure 146 may be in contact with the second dielectric layer 115. When the semiconductor device 100 is in an arrangement as shown in FIG. 1, the first isolation structure 146 may be located above the conductive structure 114. In addition, the first isolation structure 146 may extend along the D3 direction.

In some implementations, materials of the first isolation structure 146 and the second dielectric layer 115 may be the same or different, to which the present disclosure has no limitations. In a case where the materials of the first isolation structure 146 and the second dielectric layer 115 are different, the material of the second dielectric layer 115 may be, for example, silicon oxide, and the material of the first isolation structure 146 may be, for example, silicon nitride.

In some implementations, the semiconductor device 100 may further comprise a second isolation structure 147. The second isolation structure 147 may be located on a side (e.g., a surface) of the gate structure 112 away from the first dielectric layer 113 in the D2 direction.

In some implementations, the second isolation structure 147 and the conductive structure 114 are arranged alternately in the D2 direction. In the D2 direction, the gate structure 112 is disposed symmetrically with respect to the second isolation structure 147.

In some implementations, the semiconductor device 100 may further comprise a bit line structure 144. The bit line structure 144 may be located on a side of an end of the semiconductor body 111 and may extend along the D2 direction. The bit line structure 144 may be connected to a row of semiconductor bodies 111 arranged in a D2 direction (e.g., parts of respective ends of the row of semiconductor bodies 111 connected to each other). In addition, a plurality of bit line structures 144 may be spaced apart from each other in the D3 direction. The material of the bit line structure 144 may comprise one or more of titanium, titanium nitride, tantalum, tantalum nitride, tungsten, molybdenum, copper, aluminum, ruthenium, metal silicide, or any other suitable conductive material.

In some implementations, in the D1 direction, the capacitor C may have a spacing distance greater than zero from the semiconductor body 111. The capacitor C may comprise, but is not limited to, a stack capacitor, a cup capacitor, a pillar capacitor, and a cylinder capacitor. The capacitor C may comprise a first electrode, a second electrode, and an insulation dielectric layer located between the first electrode and the second electrode. For example, the first electrode of the capacitor C may be connected to an end of the semiconductor body 111 away from the bit line structure 144.

In some implementations, as shown in FIGS. 1 and 2, the first electrode 131 in the capacitor C may extend along the D1 direction. For example, the first electrode 131 may be substantially a hollow pillar structure or a solid pillar structure (not shown). When the first electrode 131 is a hollow pillar structure, a supporting pillar 135 may be provided inside the first electrode 131. In this implementation, capacitor C may be referred to as a pillar capacitor. The material of the first electrode 131 may comprise one or more of titanium, titanium nitride, tantalum, tantalum nitride, tungsten, molybdenum, copper, aluminum, ruthenium, or any other suitable conductive material. For example, the material of the first electrode 131 may be titanium nitride. Alternatively, in a case where the supporting pillar 135 is provided, the material of the supporting pillar 135 may comprise polysilicon (e.g., doped polysilicon).

In some implementations, the insulation dielectric layer 132 in the capacitor C may cover at least part of the first electrode 131. When the semiconductor device 100 is in an arrangement as shown in FIG. 1, the insulation dielectric layer 132 may cover at least part of the side surface and the top surface of the first electrode 131. The material of the insulation dielectric layer 132 may comprise one or more of silicon oxide, silicon nitride, silicon oxynitride, high dielectric constant material, or any other suitable insulation material. The high dielectric constant material may comprise, but is not limited to, aluminum oxide, titanium oxide, tantalum oxide, hafnium oxide, zirconium oxide, and the like.

In some implementations, the second electrode 133 in the capacitor C may cover the insulation dielectric layer 132. As such, the second electrodes 133 of a plurality of capacitors C are connected to each other. The material of the second electrode 133 may comprise one or more of titanium, titanium nitride, tantalum, tantalum nitride, tungsten, molybdenum, copper, aluminum, ruthenium, silicon, germanium, germanium silicon, or any other suitable conductive material. For example, the second electrode 133 is composed of a titanium nitride layer and a polysilicon layer sequentially outward from the insulation dielectric layer 132.

In some implementations, the semiconductor device 100 may further comprise a first insulation layer 134-1. The first insulation layer 134-1 may be located on a surface of the isolation layer 142 away from the semiconductor body 111 in the D1 direction and located between adjacent first electrodes 131. The isolation layer 142 will be described in detail below. For example, the first insulation layer 134-1 may extend along the D2 direction and the D3 direction. The first insulation layer 134-1 may surround the end of each first electrode 131. In other words, each first electrode 131 may extend through the first insulation layer 134-1. When the semiconductor device 100 is in an arrangement as shown in FIG. 1, the bottom surface of the first insulation layer 134-1 may be substantially flush with the bottom surface of the first electrode 131.

In some implementations, the semiconductor device 100 may further comprise a second insulation layer 134-2 and a third insulation layer 134-3. The second insulation layer 134-2 may be located on a side of the first insulation layer 134-1 away from the semiconductor body 111 in the D1 direction. The third insulation layer 134-3 may be located on a side of the second insulation layer 134-2 away from the first insulation layer 134-1 in the D1 direction. The second insulation layer 134-2 and the third insulation layer 134-3 may both extend along the D2 direction and the D3 direction. The first insulation layer 134-1, the second insulation layer 134-2 and the third insulation layer 134-3 may be spaced apart from each other in the D1 direction. For example, the first insulation layer 134-1, the second insulation layer 134-2 and the third insulation layer 134-3 are substantially parallel to each other. The second insulation layer 134-2 may at least partially surround a middle portion of each first electrode 131, and the third insulation layer 134-3 may at least partially surround another end of each first electrode 131. In other words, each first electrode 131 may extend through the second insulation layer 134-2 and the third insulation layer 134-3. It should be noted that, compared with the first insulation layer 134-1, the second insulation layer 134-2 and the third insulation layer 134-3 may have hollow portions. The insulation dielectric layer 132 and the second electrode 133 in the capacitor C may extend in the hollow portion.

In some implementations, the materials of the first insulation layer 134-1, the second insulation layer 134-2 and the third insulation layer 134-3 may comprise one or more of silicon oxide, silicon nitride, silicon oxynitride, or any other suitable insulation material. In some implementations, materials of the first insulation layer 134-1, the second insulation layer 134-2 and the third insulation layer 134-3 may be boron-doped silicon nitride. In some other examples, the materials of the first insulation layer 134-1, the second insulation layer 134-2 and the third insulation layer 134-3 may be different. For example, the material of the first insulation layer 134-1 may be boron-doped silicon nitride, and the second insulation layer 134-2 and the third insulation layer 134-3 may be other insulation materials.

It should be noted that the semiconductor device 100 may further comprise another number of insulation layers. As an example, at least one of the second insulation layer 134-2 or the third insulation layer 134-3 may be omitted. As another example, a greater number (e.g., greater than 3) of insulation layers (not shown) may be provided in addition to the first to third insulation layers 134-1 to 134-3. The number of the insulation layers other than the first insulation layer 134-1 is not specifically limited in the present disclosure. These insulation layers (including the first insulation layer 134-1) can play a supporting role in the manufacturing process of capacitor C. In addition, in a case where the semiconductor device 100 comprises the above-mentioned insulation layers (including the first insulation layer 134-1), the insulation dielectric layer 132 may cover these insulation layers (including the first insulation layer 134-1).

In an example, referring to FIG. 1, the semiconductor body 111 may be connected to a capacitor C (e.g., the first electrode 131) through a connection structure. The connection structure may affect the connection performance of the semiconductor body 111 and the capacitor C (e.g., the first electrode 131), such as electric leakage between adjacent first electrodes 131. In the semiconductor device 100 provided by the example of the present disclosure, as shown in FIG. 1 and FIG. 2, by modifying the first connection structure 120, that is, the size d1 of the first end 121 of the first connection structure 120 in the D2 direction is smaller than the size d2 of the second end 122 of the first connection structure 120 in the D2 direction, the connection performance of the first connection structure 120 is improved, the risk of electric leakage between the adjacent first electrodes 131 is reduced, and the yield of the semiconductor device 100 is improved.

The connection structure (including the first connection structure 120) between the semiconductor body 111 and the capacitor Cis further described below with reference to FIG. 1 and FIG. 2.

In some implementations, as shown in FIGS. 1 and 2, the first end 121 of the first connection structure 120 may be in contact with the first electrode 131. The second end 122 of the first connection structure 120 may be away from the first electrode 131 in the D1 direction. For example, both the first end 121 and the second end 122 may be substantially circular. As such, the size d1 of the first end 121 in the D2 direction may be a diameter. The size d2 of the second end 122 in the D2 direction may also be a diameter.

In some implementations, as shown in FIG. 2, the first connection structure 120 may comprise a body portion 123 and an adhesive layer 124. The body portion 123 may have a first end 121 and a third end 125 opposite to the first end 121 in the D1 direction. As such, the body portion 123 may be in contact with the first electrode 131. For example, the size d1 of the first end 121 in the D2 direction may be smaller than the size d3 of the end of the first electrode 131 in contact with the first end 121 in the D2 direction. The adhesive layer 124 may cover the third end 125 and part of a side surface of the body portion 123. For example, the adhesive layer 124 may be substantially cup-shaped, and the body portion 123 is located in the cup-shaped adhesive layer 124 and protrudes from the adhesive layer 124. As such, the adhesive layer 124 may have a second end 122. The portion of the body portion 123 taken along the plane defined by the D1 direction and the D2 direction protruding from the adhesive layer 124 may be substantially an isosceles trapezoid. When the semiconductor device 100 is in an arrangement as shown in FIG. 2, the size of the upper side of the isosceles trapezoid may be d1, and the size of the lower side of the isosceles trapezoid may be greater than d1.

In some implementations, a size (e.g., diameter) d1 of the first end 121 in the D2 direction may be less than a size d4 of the third end 125 in the D2 direction. For example, the size d4 of the third end 125 in the D2 direction may also be a diameter.

In some implementations, in the D1 direction, the end 126 of the adhesive layer 124 away from the semiconductor body 111 may be located on a side of the first end 121 away from the capacitor C.

In some implementations, the first electrode 131 is in contact with the first end 121, and a spacing distance between the first electrode 131 and the end 126 of the adhesive layer 124 away from the semiconductor body 111 in the D1 direction is greater than zero. In other words, the first electrode 131 is not in contact with the adhesive layer 124.

In some implementations, the material of the body portion 123 may comprise one or more of tungsten, molybdenum, copper, aluminum, ruthenium, or any other suitable metal material. For example, the material of the body portion 123 may be tungsten. The material of the adhesive layer 124 may comprise one or more of titanium, titanium nitride, tantalum, tantalum nitride, or any other suitable adhesive material. For example, the material of the adhesive layer 124 may comprise titanium nitride. The adhesive layer 124 may be used to improve the bonding performance between the body portion 123 made of metal and the insulation material (for example, the isolation layer 142) on the outer side of the body portion 123, and also to prevent the metal material from diffusing to the insulation material (for example, the isolation layer 142) on the outer side.

In some implementations, the semiconductor device 100 may further comprise an insulation structure 143. The insulation structure 143 may be located between the first electrode 131 and the adhesive layer 124 in the D1 direction. For example, the insulation structure 143 may be a ring-shaped structure and may surround a portion of the body portion 123 not covered by the adhesive layer 124. As an example, the insulation structure 143 may also be located between the first insulation layer 134-1 and the adhesive layer 124 in the D1 direction. The material of the insulation structure 143 may be the same as the material of the first insulation layer 134-1, for example, boron-doped silicon nitride. For example, the insulation structure 143 and the first insulation layer 134-1 may be formed in the same thin film process of the manufacturing process. When the materials of the insulation structure 143 and the first insulation layer 134-1 are the same, there is no obvious interface between the insulation structure 143 and the first insulation layer 134-1.

In some implementations, as shown in FIG. 2, the size of the end of the insulation structure 143 close to the first electrode 131 in the D2 direction is greater than the size of the end of the insulation structure 143 close to the adhesive layer 124 in the D2 direction. For example, the size of the insulation structure 143 in the D2 direction may refer to the difference between its outer diameter and inner diameter. The insulation structure 143 taken along the plane defined by the D1 direction and the D2 direction may be substantially an isosceles trapezoid. When the semiconductor device 100 is in an arrangement as shown in FIG. 2, the size of the upper side of the isosceles trapezoid may be larger than the size of the lower side of the isosceles trapezoid.

In some implementations, as shown in FIGS. 1 and 2, the semiconductor device 100 may further comprise an isolation layer 142. The isolation layer 142 may be located between adjacent first connection structures 120. The insulation structure 143 may be located between the body portion 123 and the isolation layer 142. For example, the isolation layer 142 may extend along the D2 direction and the D3 direction. When the semiconductor device 100 is in an arrangement as shown in FIG. 1, the top surface of the isolation layer 142 may be substantially flush with the first end 121, and the top surface of the isolation layer 142 may be in contact with the first insulation layer 134-1. For example, the first connection structure 120 and the insulation structure 143 surrounding the first connection structure 120 may extend in a portion of the isolation layer 142 along the D1 direction. For example, the material of the isolation layer 142 may comprise silicon nitride.

In some implementations, the semiconductor device 100 may further comprise a second connection structure 141. The second connection structure 141 may extend along the D1 direction and may be connected to the first connection structure 120 and the semiconductor body 111. For example, the second connection structure 141 may be substantially aligned with the first connection structure 120 in the D1 direction. One end of the second connection structure 141 may be in contact with the second end 122 of the first connection structure 120, and the other end of the second connection structure 141 may be in contact with the semiconductor body 111. In addition, the isolation layer 142 may also be located between adjacent second connection structures 141. In other words, the second connection structure 141 may extend in another portion of the isolation layer 142 along the D1 direction.

In some implementations, the material of the second connection structure 141 may comprise a semiconductor, such as a doped semiconductor. As an example, the material of the second connection structure 141 may comprise doped polysilicon. The second connection structure 141 may be configured to form an ohmic contact with the first connection structure 120 to reduce the contact resistance.

In some implementations, the first connection structure 120 and the second connection structure 141 together serve to connect the capacitor C and the semiconductor body 111 (or transistor T). Specifically, the first electrode 131 of the capacitor C may be connected with, for example, the source of the transistor T through the first connection structure 120 and the second connection structure 141. The capacitor C and the transistor T may constitute a memory cell, such as a DRAM memory cell. The capacitor C may be used to achieve data storage, and the transistor T may serve as a switch for accessing data in the capacitor C.

In some implementations, as shown in FIG. 1, the semiconductor device 100 may further comprise a peripheral circuit structure 145. The peripheral circuit structure 145 may be located on a side of the semiconductor body 111 away from the capacitor C in the D1 direction. Alternatively, the peripheral circuit structure 145 may be located on a side (not shown) of the capacitor C away from the semiconductor body 111 in the D1 direction. In other words, the semiconductor body 111 (or the transistor T), the capacitor C and the peripheral circuit structure 145 may be stacked together in the D1 direction.

In some implementations, the peripheral circuit structure 145 may comprise a peripheral circuit for controlling any suitable digital, analog, and/or mixed-signal of the operation of the memory cell array. For example, the peripheral circuit may comprise one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portion (e.g., sub-circuit) of the aforementioned functional circuit, or any active or passive component (e.g., transistor, diode, resistor, or capacitor) of the circuit.

Some examples of the present disclosure further provide another semiconductor device. As shown in FIGS. 1 and 2, the semiconductor device 100 may comprise a semiconductor body 111, a capacitor C, a first connection structure 120, and an insulation structure 143. The semiconductor body 111 may extend along the D1 direction. The capacitor C may be located on a side of the semiconductor body 111 in the D1 direction, and may comprise a first electrode 131 extending along the D1 direction. The first connection structure 120 may extend along the D1 direction to the first electrode 131, and may comprise a body portion 123 and an adhesive layer 124. The adhesive layer 124 may cover an end (e.g., the third end 125) of the body portion 123 close to the semiconductor body 111 and part of the side surface of the body portion 123. The insulation structure 143 may be located between the first electrode 131 and the adhesive layer 124 in the D1 direction.

In some implementations, the size of the end of the insulation structure 143 close to the first electrode 131 in the D2 direction may be greater than the size of the end 126 of the insulation structure 143 close to the adhesive layer 124 in the D2 direction. For example, the size of the insulation structure 143 in the D2 direction may refer to the difference between the outer diameter and inner diameter of the insulation structure 143.

In some implementations, the semiconductor device 100 may further comprise an isolation layer 142. The isolation layer 142 may be located between adjacent first connection structures 120. The insulation structure 143 may be located between the body portion 123 and the isolation layer 142.

In some implementations, the semiconductor device 100 may further comprise a first insulation layer 134-1. The first insulation layer 134-1 may be located on a surface of the isolation layer 142 away from the semiconductor body 111 in the D1 direction and located between adjacent first electrodes 131. For example, the material of the isolation layer 142 comprises silicon nitride.

In some implementations, the material of the first insulation layer 134-1 may be the same as the material of the insulation structure 143. For example, the insulation material may comprise boron-doped silicon nitride.

In some implementations, the semiconductor device 100 may further comprise a second connection structure 141. The second connection structure 141 may extend along the D1 direction and may be connected to the first connection structure 120 and the semiconductor body 111. For example, the material of the second connection structure 141 comprises a semiconductor. For example, the semiconductor may comprise doped polysilicon.

Since the components in the semiconductor device 100 have been described in detail above, they will not be repeated in the present disclosure.

In the semiconductor device 100 provided by the example of the present disclosure, by providing the insulation structure 143 located between the first electrode 131 and the adhesive layer 124 in the D1 direction, the connection performance of the first connection structure 120 is improved, the risk of electric leakage between adjacent first electrodes 131 is reduced, and the yield of the semiconductor device 100 is improved.

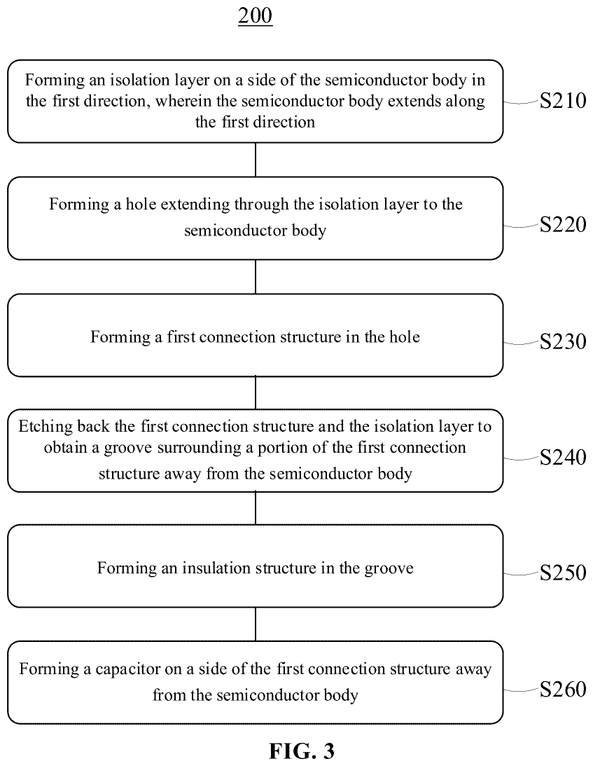

Some examples of the present disclosure further provide a manufacturing method of a semiconductor device. FIG. 3 is a schematic flowchart of a manufacturing method of a semiconductor device according to an example of the present disclosure. As shown in FIG. 3, the manufacturing method 200 of the semiconductor device (hereinafter referred to as the manufacturing method 200) may comprise the following operations.

S210: forming an isolation layer on a side of the semiconductor body in the first direction, wherein the semiconductor body extends along the first direction.

S220: forming a hole extending through the isolation layer to the semiconductor body.

S230: forming a first connection structure in the hole.

S240: etching back the first connection structure and the isolation layer to obtain a groove surrounding a portion of the first connection structure away from the semiconductor body.

S250: forming an insulation structure in the groove.

S260: forming a capacitor on a side of the first connection structure away from the semiconductor body.

In the manufacturing method 200 provided by the example of the present disclosure, after the first connection structure is formed, the first connection structure and the isolation layer are etched back, so that the risk of electric leakage between adjacent first connection structures can be reduced, and the connection performance of the first connection structure can be improved and the manufacturing yield can be improved during the scaling down of the semiconductor device (for example, the spacing distance between the adjacent first connection structures is reduced).

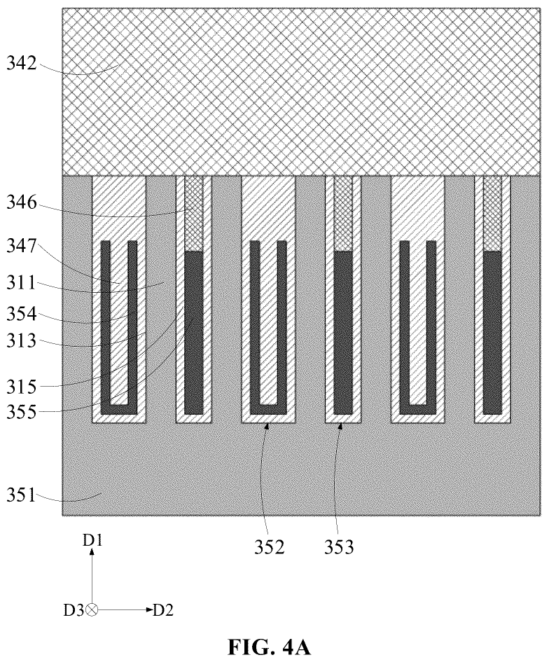

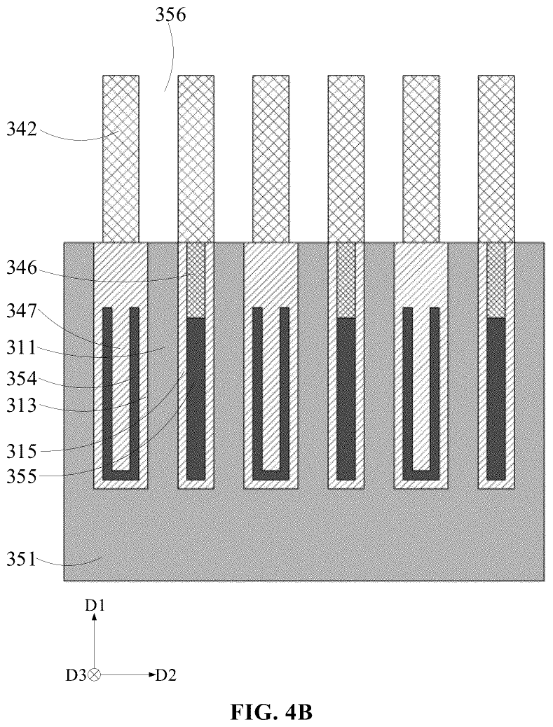

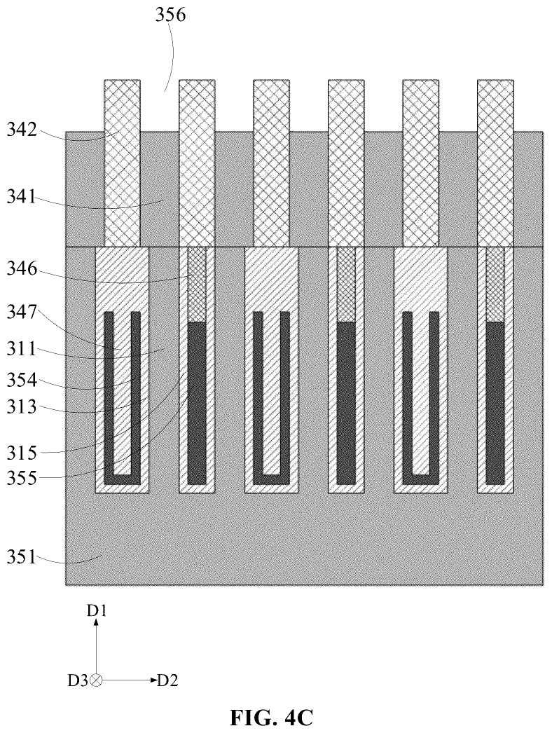

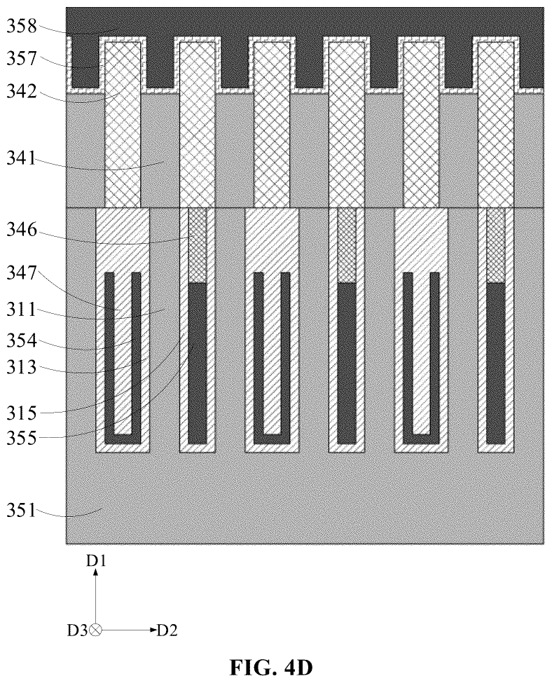

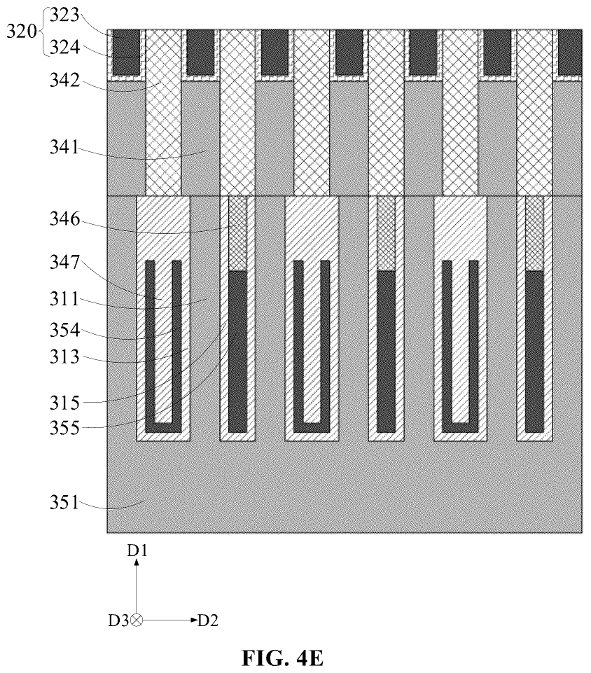

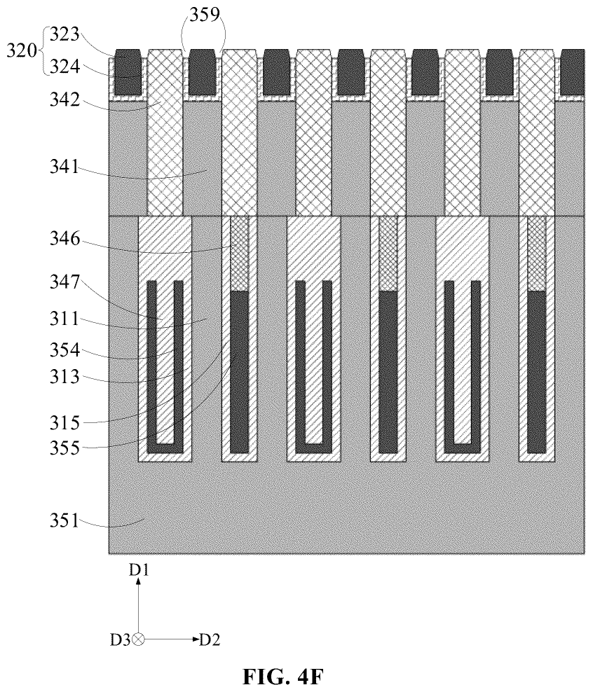

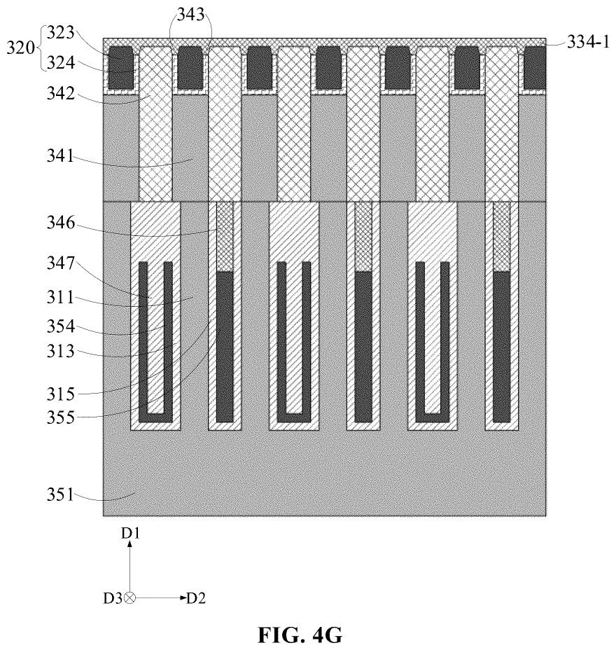

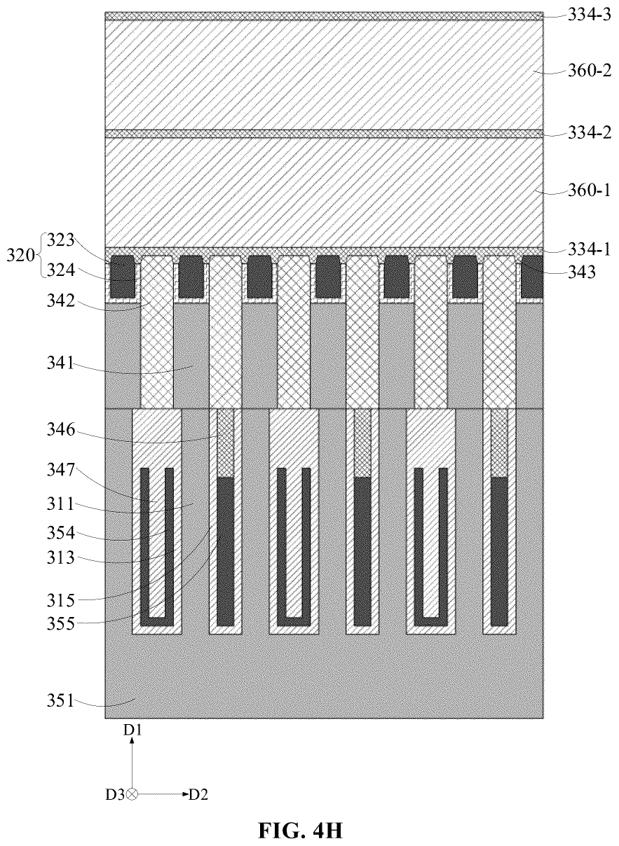

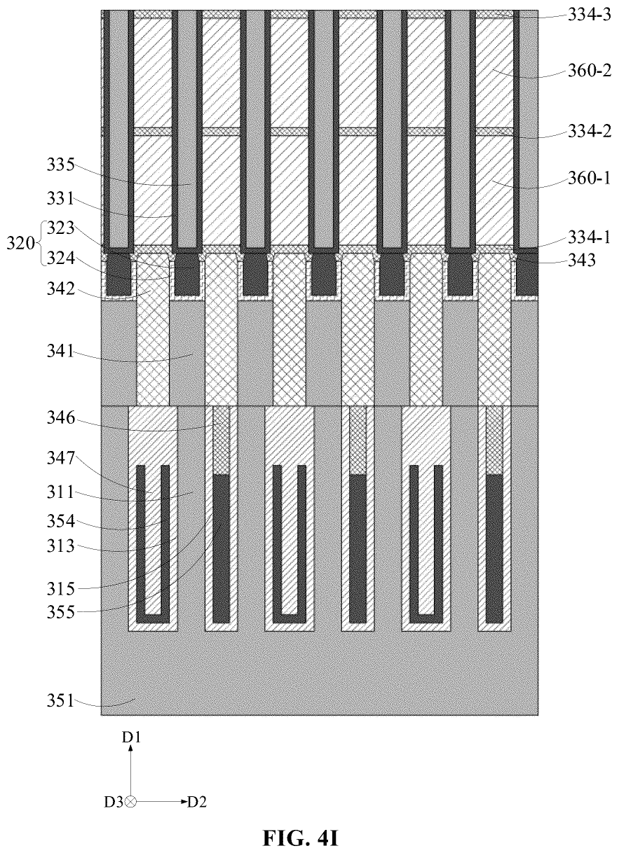

FIG. 4A to FIG. 4J are schematic cross-sectional views of a semiconductor device in a manufacturing process according to an example of the present disclosure. Specifically, FIG. 4A illustrates an intermediate structure after forming the semiconductor body and the isolation layer. FIG. 4B illustrates an intermediate structure after forming the holes. FIG. 4C illustrates an intermediate structure after forming the second connection structure. FIG. 4D illustrates an intermediate structure after depositing the conductive material. FIG. 4E illustrates an intermediate structure after forming the first connection structure. FIG. 4F illustrates an intermediate structure after forming the grooves. FIG. 4G illustrates an intermediate structure after forming the first insulation layer and the insulation structure. FIG. 4H illustrates an intermediate structure after forming the first sacrificial layer, the second insulation layer, the second sacrificial layer, and the third insulation layer. FIG. 4I illustrates an intermediate structure after forming the first electrode. FIG. 4J illustrates the semiconductor device after forming the capacitor.

The manufacturing method 200 comprising operations S210 to S260 is described below with reference to FIGS. 4A to 4J.

The manufacturing method 200 starts at S210. As shown in FIG. 4A, the semiconductor body 311 extending along the D1 direction may be formed by etching the substrate 351. For example, the substrate 351 may extend along the D2 direction and the D3 direction. In the process of forming the semiconductor body 311, a plurality of first trenches (not shown) extending along the D2 direction may be formed on a side of the substrate 351 in the D1 direction. Next, an insulation material may be filled in the first trench. Then, the substrate 351 and the insulation material may be etched on a side of the substrate 351 in the D1 direction to form a plurality of second trenches 352 extending along the D3 direction and a plurality of third trenches 353 extending along the D3 direction. The second trenches 352 and the third trenches 353 are arranged alternately in the D2 direction. Since the extending direction of the first trench intersect the extending direction of the second trench 352 and the extending direction of the first trench intersect the extending direction of the third trench 353, a plurality of semiconductor bodies 311 spaced apart from each other in the D2 direction and the D3 direction may be formed, and each of the semiconductor bodies 311 may extend along the D1 direction.

In some implementations, a depth of the first trench (not shown) may be greater than a depth of the second trench 352, and may be greater than a depth of the third trench 353.

In some implementations, the depth of the second trench 352 may be equal to the depth of the third trench 353.

In some implementations, the material of the substrate 351 may comprise silicon, germanium, silicon germanium, silicon carbide, gallium nitride, or any other suitable semiconductor material. In one example, the substrate 351 may be a silicon substrate, such as a monocrystalline silicon substrate. Since the semiconductor body 311 is formed by etching the substrate 351, the material of the semiconductor body 311 is the same as the material of the substrate 351. For example, the material of the semiconductor body 311 may be silicon (e.g., monocrystalline silicon).

In some implementations, as shown in FIG. 4A, the manufacturing method 200 may further comprise an operation of forming the first dielectric layer 313, the initial gate structure 354, the second dielectric layer 315, the initial conductive structure 355, the first isolation structure 346, and the second isolation structure 347.

For example, a first dielectric layer 313 may be formed on an inner wall of the second trench 352 by using a thin film deposition process of chemical vapor deposition (CVD), physical vapor deposition (PVD), atomic layer deposition (ALD), or any combination thereof, and an initial gate structure 354 may be formed on a surface of the first dielectric layer 313. For example, a portion of the initial gate structure 354 in the opening of the second trench 352 may be removed by an etching (e.g., at least one of wet etching or dry etching) process, such that a spacing distance between the top surface of the initial gate structure 354 and the top surface of the semiconductor body 311 is greater than zero. Further, a second isolation structure 347 may be formed on the inner side of the initial gate structure 354. Alternatively, the second isolation structure 347 may also be filled at top of the initial gate structure 354. For example, from the D1 direction, the initial gate structure 354 may be substantially U-shaped.

For example, the second dielectric layer 315 may be formed on the inner wall of the third trench 353 by using a thin film deposition process of CVD, PVD, ALD, or any combination thereof, and the initial conductive structure 355 may be formed on the inner side of the second dielectric layer 315. For example, a portion of the initial conductive structure 355 in an opening of the third trench 353 may be removed by an etching (e.g., at least one of wet etching or dry etching) process, such that a spacing distance between a top surface of the initial conductive structure 355 and a top surface of the semiconductor body 311 is greater than zero, and such that a top surface of the initial conductive structure 355 is lower than a top surface of the initial gate structure 354. Further, a first isolation structure 346 may be formed in a top space of the initial conductive structure 355.

It should be noted that the sequence of forming the first dielectric layer 313, the initial gate structure 354 and the second isolation structure 347 and forming the second dielectric layer 315, the initial conductive structure 355 and the first isolation structure 346 is not limited in the present disclosure.

In S210, the isolation layer 342 on a side (e.g., surface) of the semiconductor body 311 in the D1 direction may be formed by using a thin film deposition process of CVD, PVD, ALD, or any combination thereof. For example, the material of the isolation layer 342 may comprise silicon nitride.

The manufacturing method 200 proceeds to S220. As shown in FIG. 4B, a hole 356 extending through the isolation layer 342 to the semiconductor body 311 is formed by an etching (e.g., at least one of wet etching or dry etching) process. For example, there are a plurality of holes 356. Each of the holes 356 may extend along the D1 direction and expose the corresponding semiconductor body 311.

The manufacturing method 200 proceeds to S230. In some implementations, as shown in FIG. 4C, the second connection structure 341 may be formed at bottom of the hole 356 by using a thin film deposition process such as CVD, PVD, ALD, or any combination thereof and/or an epitaxial growth process. The material of the second connection structure 341 may comprise a semiconductor. For example, the semiconductor may comprise doped polysilicon.

In some implementations, the adhesive material 357 and the metal material 358 may be deposited on the top of the hole 356 (e.g., the top sidewall of the hole 356 and the top surface of the second connection structure 341) and the surface of the isolation layer 342 away from the semiconductor body 311 by using a thin film deposition process of CVD, PVD, ALD, or any combination thereof, as shown in FIG. 4D. For example, the adhesive material 357 and the metal material 358 may be referred to as conductive materials. Further, a mechanical chemical polishing (CMP) process may be used to remove a portion of the conductive material (e.g., adhesive material 357 and metal material 358) deposited on the surface of the isolation layer 342 away from the semiconductor body 311. The isolation layer 342 may be exposed after the portion of the conductive material is removed. The remaining conductive material (e.g., the adhesive material 357 and the metal material 358) on the top of the hole 356 may be the first connection structure 320, as shown in FIG. 4E. For example, the remaining adhesive material 357 may be the adhesive layer 324, and the remaining metal material 358 may be the body portion 323. As such, the first connection structure 320 may be formed on the top of the hole 356.

It should be noted that the present disclosure describes in detail an example in which the second connection structure 341 is formed at bottom of the hole 356 and the first connection structure 320 is formed at top of the hole 356, wherein the second connection structure 341 may be configured to form an ohmic contact with the first connection structure 320, thereby reducing the contact resistance. In other examples, the second connection structure 341 may also be omitted, and the first connection structure 320 may be directly formed in the hole 356.

The manufacturing method 200 proceeds to S240. As shown in FIG. 4F, the first connection structure 320 and the isolation layer 342 are etched back (e.g., dry etching) to obtain a groove 359 surrounding a portion of the first connection structure 320 away from the semiconductor body 311. For example, in the process of etching back the first connection structure 320 and the isolation layer 342, the adhesive layer 324, the body portion 323 and the isolation layer 342 may be etched back to obtain the groove 359 surrounding the portion of the body portion 323 away from the semiconductor body 311. For example, an etching material (for example, an etching gas) in etching back process has etching selectivity for the adhesion layer 324, the body portion 323, and the isolation layer 342. Under the condition that other etching conditions are the same, an etching selectivity ratio of the etching material (for example, etching gas) to the adhesive layer 324 may be greater than that of the etching material to the body portion 323 and the isolation layer 342. As such, in the D1 direction, the removed portion of the body portion 323 and the isolation layer 342 may be less than the removed portion of the adhesive layer 324, such that the groove 359 is formed.

In some implementations, as shown in FIG. 4F, the top width of the groove 359 may be greater than the bottom width of the groove 359. As such, the groove 359 taken along the plane defined by the D1 direction and the D2 direction may be substantially an isosceles trapezoid, and the size of the upper side of the isosceles trapezoid is greater than the size of the lower side of the isosceles trapezoid. The portion of the body portion 323 taken along the plane defined by the D1 direction and the D2 direction exposed in the groove may be also substantially an isosceles trapezoid, and the size of the upper side of the isosceles trapezoid is smaller than the size of the lower side of the isosceles trapezoid.

In the process of removing a portion of the conductive material (e.g., the adhesive material 357 and the metal material 358) deposited on the surface of the isolation layer 342 away from the semiconductor body 311 to form the first connection structure 320, the conductive material (e.g., the adhesive material 357 and the metal material 358) may diffuse to the top of the isolation layer 342 between adjacent first connection structures 320, resulting in electric leakage between adjacent first connection structures 320. As the spacing distance between adjacent first connection structures 320 decreases, the probability of electric leakage between adjacent first connection structures 320 increases. In the manufacturing method 200 provided by the example of the present disclosure, after the first connection structure 320 is formed, the first connection structure 320 and the isolation layer 342 are etched back, so that the portion on the top of the isolation layer 342 to which the conductive material is diffused is removed, and the risk of electric leakage between the adjacent first connection structures 320 can be reduced. During the scaling down of the semiconductor device (for example, the spacing distance between the adjacent first connection structures 320 is reduced), the connection performance of the first connection structure 320 is improved, and the yield is also improved.

The manufacturing method 200 proceeds to S250. In some implementations, as shown in FIGS. 4F and 4G, an insulation structure 343 may be formed in the groove 359 by using a thin film deposition process of CVD, PVD, ALD, or any combination thereof. For example, in the same film deposition process, the first insulation layer 334-1 may be formed on the surface of the isolation layer 342 away from the semiconductor body 311 in the D1 direction. Thus, the insulation structure 343 may have the same outer profile as the groove 359. In addition, the insulation structure 343 may be the same as the material of the first insulation layer 334-1, for example, boron-doped silicon nitride.

The manufacturing method 200 proceeds to S260. In some implementations, as shown in FIG. 4H to FIG. 4J, forming the capacitor C on a side of the first connection structure 320 away from the semiconductor body 311 may be implemented by the following operations.

First, as shown in FIG. 4H, a first sacrificial layer 360-1, a second insulation layer 334-2, a second sacrificial layer 360-2, and a third insulation layer 334-3 may be sequentially formed on the surface of the first insulation layer 334-1 by using a thin film deposition process of CVD, PVD, ALD, or any combination thereof. Each of the film layers extends along the D2 direction and the D3 direction. For example, a size of the first sacrificial layer 360-1 in the D1 direction may be greater than a size of each of the first insulation layer 334-1 to the third insulation layer 334-3 in the D1 direction, and a size of the second sacrificial layer 360-2 in the D1 direction may also be greater than a size of each of the first insulation layer 334-1 to the third insulation layer 334-3 in the D1 direction. The materials of the first sacrificial layer 360-1 and the second sacrificial layer 360-2 may comprise silicon oxide, polysilicon, carbon, or any other suitable material that could be easily removed with respect to the first insulation layer 334-1 to the third insulation layer 334-3. The materials of the first insulation layer 334-1 to the third insulation layer 334-3 may be different from the materials of the first sacrificial layer 360-1 and the second sacrificial layer 360-2. For example, the materials of the first insulation layer 334-1 to the third insulation layer 334-3 may comprise boron-doped silicon nitride, and the materials of the first sacrificial layer 360-1 and the second sacrificial layer 360-2 may comprise silicon oxide.

It should be noted that the number of the sacrificial layers and the number of the second insulation layers sandwiched between the sacrificial layers is not specifically limited in the present disclosure. For example, the number of sacrificial layers may be greater than 2, and the number of second insulation layers may be greater than 1. In addition, the third insulation layer may be omitted.

Further, as shown in FIG. 4I, a first electrode hole (corresponding to the outer profile of the first electrode 331) extending to the first connection structure 320 along the D1 direction may be formed by an etching (e.g., at least one of dry etching or wet etching) process. For example, the first electrode hole may extend through the third insulation layer 334-3, the second sacrificial layer 360-2, the second insulation layer 334-2, the first sacrificial layer 360-1 and the first insulation layer 334-1 sequentially. The first electrode hole may expose the body portion 323 and the insulation structure 343. Subsequently, the first electrode 331 may be formed on the inner wall of the first electrode hole by using a thin film deposition process of CVD, PVD, ALD, or any combination thereof, and the supporting pillar 335 may be formed on the inner side of the first electrode 331. The first electrode 331 may extend along the D1 direction and may be in contact with the body portion 323 of the first connection structure 320 and the insulation structure 343. Alternatively, after forming the first electrode hole, a conductive material may be filled in the first electrode hole to form a solid first electrode (not shown).

Further, an etching (e.g., dry etching) process may be used to remove a portion of the third insulation layer 334-3 and expose the second sacrificial layer 360-2. Then, an etching (e.g., wet etching) process may be used to remove the second sacrificial layer 360-2. Next, an etching (e.g., dry etching) process may be used to remove a portion of the second insulation layer 334-2 and expose the first sacrificial layer 360-1, and then an etching (e.g., wet etching) process may be used to remove the first sacrificial layer 360-1. The first to third insulation layers 334-1 to 334-3 may serve to support after the first sacrificial layer 360-1 and the second sacrificial layer 360-2 are removed.

Further, as shown in FIG. 4J, an insulation dielectric layer 332 may be formed on the surfaces of the first electrode 331, the first insulation layer 334-1, the second insulation layer 334-2 and the third insulation layer 334-3 by using a thin film deposition process of CVD, PVD, ALD, or any combination thereof. Then, a second electrode 333 composed of at least one conductive material may be formed on the surface of the insulation dielectric layer 332. The first electrode 331 and the insulation dielectric layer 332 and the second electrode 333 sequentially covering the first electrode 331 may constitute a capacitor C.

In some implementations, as shown in FIG. 4J, the manufacturing method 200 may further comprise an operation of forming the gate structure 312 and the conductive structure 314 by a “back side process”. For example, the “back side process” is performed after forming the capacitor C. In an example, the insulation material filled between the portion of the substrate 351 as shown in FIG. 4I and the first trench (not shown) may be removed. As described above, since the depth of the first trench is greater than the depth of the second trench 352 (referring to FIG. 4A) and is greater than the depth of the third trench 353 (referring to FIG. 4A), after the insulation material filled between the portion of the substrate 351 and the first trench (not shown) is removed, the ends of the row of semiconductor bodies 311 arranged in the D2 direction away from the first connection structure 320 may be connected to each other. Further, the ends of the initial gate structures 354 connected to each other as shown in FIG. 4I may be removed from a side of the semiconductor body 311 away from the first connection structure 320, so that the initial gate structure 354 is divided into two gate structures 312 arranged symmetrically with respect to the second isolation structure 347. A portion of the initial conductive structure 355 as shown in FIG. 4I may also be removed from a side of the semiconductor body 311 away from the first connection structure 320, thereby forming the conductive structure 314. It should be noted that, in the process of removing a portion of the initial gate structure 354 and a portion of the initial conductive structure 355, the size of the gate structure 312 and the conductive structure 314 in the D1 direction can be ensured by controlling process parameters. The semiconductor body 311, the gate structure 312 corresponding to the semiconductor body 311, and the first dielectric layer 313 therebetween may constitute the transistor T. The transistor T may be connected to the capacitor C through, for example, the second connection structure 341 and the first connection structure 320.

In some implementations, the manufacturing method 200 may further comprise an operation of forming the gate structure and the conductive structure by a “front side process”. For example, the “front side process” is performed before forming capacitor C.

For example, referring to FIG. 4A, as described above, after the second trench 352 and the third trench 353 are formed, an insulation material may be filled at bottom of the second trench 352. Then, a first dielectric layer may be formed on the surface of the insulation material and a sidewall of the second trench 352, and an initial gate structure may be formed on a portion of the surface of the first dielectric layer. For example, from the D3 direction, the initial gate structure may be substantially U-shaped. Then, a portion of the bottom of the initial gate structure may be removed by using a punching etching process, so that the initial gate structure is divided into two gate structures.

Similarly, an insulation material may be filled at bottom of the third trench 353. Then, a second dielectric layer may be formed on the insulation material surface and sidewalls of the third trench 353, and a conductive structure may be formed in a portion of the inner space of the second dielectric layer 115.

In some implementations, as shown in FIG. 4J, the manufacturing method 200 may further comprise an operation of forming a bit line structure 344. In an example, the bit line structure 344 may be formed on surfaces of ends of a row of semiconductor bodies 311 that are connected to each other. As such, the bit line structure 344 may extend along the D2 direction and may be connected to a row of semiconductor bodies 311 arranged along the D2 direction.

In some implementations, as shown in FIG. 4J, the manufacturing method 200 may further comprise an operation of connecting the peripheral circuit structure 345. For example, the peripheral circuit structure 345 may be bonded to a side of the semiconductor body 311 away from the capacitor C in the D1 direction. The peripheral circuit structure 345 may be manufactured in parallel with the intermediate structure of the semiconductor device described above, thereby improving the manufacturing efficiency. Alternatively, the peripheral circuit structure 345 may also be bonded to a side of the capacitor C away from the semiconductor body 311 in the D1 direction.

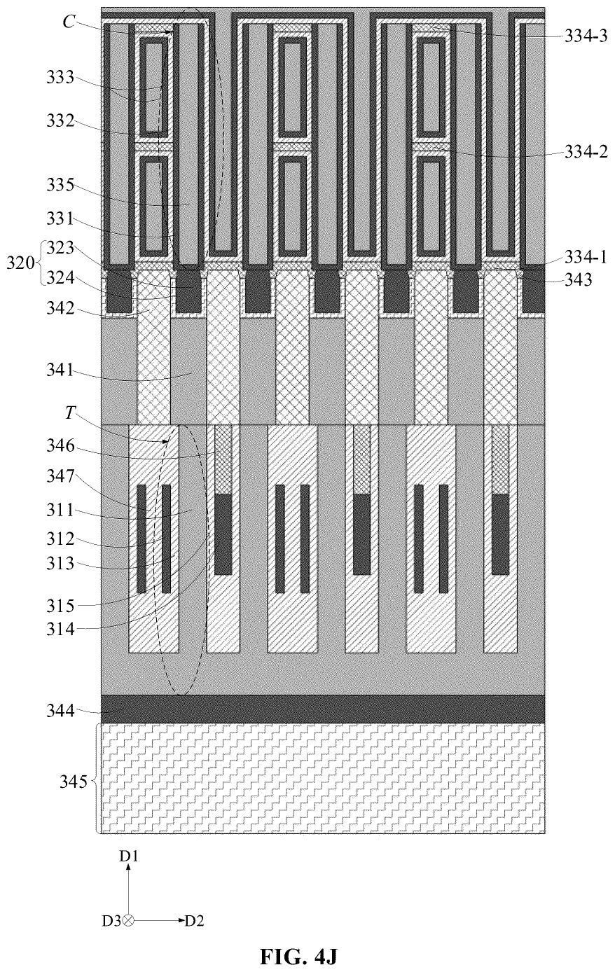

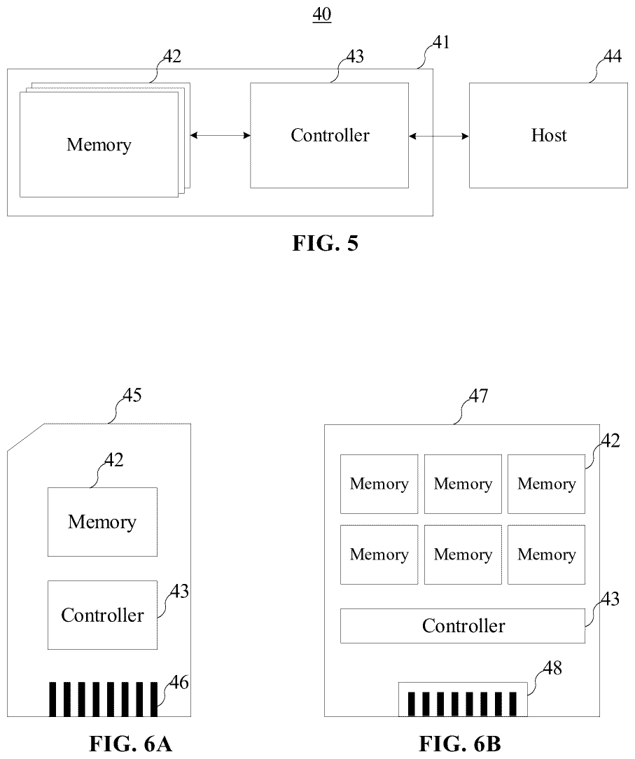

The example of the present disclosure further provides a memory system. FIG. 5 is a schematic block diagram of a system having a memory system according to an example of the present disclosure. FIG. 6A and FIG. 6B are schematic block diagrams of a memory system according to an example of the present disclosure.

As shown in FIG. 5, the system 40 may be a mobile phone, a desktop computer, a laptop computer, a tablet, an vehicle computer, a game console, a printer, a positioning device, a wearable electronic device, a smart sensor, a virtual reality (VR) device, an augmented reality (AR) device, or any other suitable electronic device which has a memory system 41 therein. As shown in FIG. 5, the system 40 may comprise a host 44 and a memory system 41 having one or more memories 42 and a controller 43. The host 44 may be a processor of an electronic device, such as a central processing unit (CPU), or may be a system-on-chip (SoC), such as an application processor (AP). The host 44 may be configured to send or receive data to and from the memory 42.

The memory 42 may comprise, for example, the semiconductor device described in any example of the present disclosure. According to some implementations, the controller 43 is coupled to the memory 42 and the host 44 and is configured to control the memory 42. The controller 43 may manage data stored in the memory 42 and communicate with the host 44. In some implementations, the controller 43 is designed to operate in a low duty cycle environment, such as a secure digital (SD) card, compact flash (CF) card, universal serial bus (USB) flash drive, or other medium used in electronic devices such as personal computers, digital cameras, mobile phones, and the like. In some implementations, the controller 43 is designed to operate in a high duty cycle environment, such as an SSD or embedded multi-media-card (eMMC) functioning as a data storage device of a mobile device, such as a smartphone, tablet, laptop, or the like, and an enterprise storage array. The controller 43 may be configured to control operations of the memory 42, such as read, erase, and program operations. The controller 43 may also be configured to manage various functions related to data stored or to be stored in the memory 42, comprising, but not limited to, bad block management, garbage collection, logical-to-physical address translation, wear leveling, and the like. In some implementations, the controller 43 is further configured to process error correction code (ECC) related to data read from or written to the memory 42. Other suitable functions may also be performed by the controller 43, such as formatting the memory 42. The controller 43 may communicate with an external device (e.g., host 44) according to a particular communication protocol. For example, the controller 43 may communicate with external devices through at least one of a variety of interface protocols, such as a USB protocol, an MMC protocol, a Peripheral Component Interconnect (PCI) protocol, a PCI-express (PCI-E) protocol, an Advanced Technology Attachment (ATA) protocol, a Serial ATA protocol, a parallel ATA protocol, a Small Computer Small Interface (SCSI) protocol, an Enhanced Small Disk Interface (ESDI) protocol, an Integrated Drive Electronics (IDE) protocol, a Firewire protocol, or the like.

The controller 43 and the one or more memories 42 may be integrated into various types of memory systems, e.g., comprised in the same package, such as a Universal Flash Storage (UFS) package or an eMMC package. That is, the memory system 41 may be implemented and packaged into different types of end electronic products. In one example as shown in FIG. 6A, the controller 43 and the single memory 42 may be integrated into the memory card 45. The memory card 45 may comprise a PC Card (PCMCIA, Personal Computer Memory Card International Association), a CF card, a smart media (SM) card, a memory stick, a multimedia card (MMC, RS-MMC, MMCmicro), an SD card (SD, miniSD, microSD, SDHC), UFS, or the like. The memory card 45 may further comprise a memory card connector 46 that couples the memory card 45 with a host (e.g., the host 44 of FIG. 5). In another example as shown in FIG. 6B, controller 43 and a plurality of memories 42 may be integrated into SSD 47. SSD 47 may further comprise an SSD connector 48 coupling SSD 47 with a host (e.g., host 44 in FIG. 5). In some implementations, the storage capacity and/or operating speed of SSD 47 is higher than that of memory card 45.

The above description is only an illustration of the present disclosure and its application principles. Those skilled in the art should understand that the protection scope involved in the present disclosure is not limited to the technical solutions of the specific combination of the technical features described above, but also cover other technical solutions formed by any combination of the above technical features or their equivalent features without departing from the technical concept, for example, the technical solutions formed by replacing the above features with the technical features having similar functions disclosed (but not limited to) in the present disclosure.

What is claimed is:

1. A semiconductor device, comprising:
a semiconductor body extending along a first direction;
a capacitor located on a side of the semiconductor body in the first direction; and
a first connection structure located between the semiconductor body and the capacitor and comprising a first end and a second end arranged in the first direction, wherein the first end is connected to the capacitor, and a size of the first end in a second direction is smaller than a size of the second end in the second direction, wherein the second direction intersects the first direction.

2. The semiconductor device of claim 1, wherein the first connection structure comprises:
a body portion having the first end and a third end opposite to the first end in the first direction; and
an adhesive layer covering the third end and part of a side surface of the body portion.

3. The semiconductor device of claim 2, wherein a size of the first end in the second direction is smaller than a size of the third end in the second direction.

4. The semiconductor device of claim 2, wherein the capacitor comprises a first electrode extending along a first direction, the first electrode is in contact with the first end, and a spacing distance between the first electrode and an end of the adhesive layer away from the semiconductor body in the first direction is greater than zero.

5. The semiconductor device of claim 2, wherein the capacitor comprises a first electrode extending along the first direction, and wherein the semiconductor device further comprises:
an insulation structure located between the first electrode and the adhesive layer in the first direction.

6. The semiconductor device of claim 5, wherein a size of an end of the insulation structure close to the first electrode in the second direction is greater than a size of an end of the insulation structure close to the adhesive layer in the second direction.

7. The semiconductor device of claim 5, further comprising:
an isolation layer located between adjacent first connection structures, wherein the insulation structure is located between the body portion and the isolation layer.

8. The semiconductor device of claim 7, further comprising:
an insulation layer located on a surface of the isolation layer away from the semiconductor body in the first direction and located between adjacent first electrodes,
wherein materials of the insulation structure and the insulation layer are the same.

9. The semiconductor device of claim 4, wherein the capacitor further comprises:
an insulation dielectric layer covering at least part of the first electrode; and
a second electrode covering the insulation dielectric layer.

10. The semiconductor device of claim 1, further comprising:
a peripheral circuit structure located on a side of the semiconductor body away from the capacitor in the first direction or located on a side of the capacitor away from the semiconductor body in the first direction.

11. A semiconductor device, comprising:
a semiconductor body extending along a first direction;
a capacitor located on a side of the semiconductor body in the first direction and comprising a first electrode extending along the first direction;
a first connection structure extending to the first electrode along the first direction and comprising a body portion and an adhesive layer, wherein the adhesive layer covers an end of the body portion close to the semiconductor body and part of a side surface of the body portion; and
an insulation structure located between the first electrode and the adhesive layer in the first direction.

12. The semiconductor device of claim 11, wherein a size of an end of the insulation structure close to the first electrode in a second direction is greater than a size of an end of the insulation structure close to the adhesive layer in the second direction, and wherein the first direction intersects the second direction.

13. The semiconductor device of claim 11, further comprising:
an isolation layer located between adjacent first connection structures, wherein the insulation structure is located between the body portion and the isolation layer.

14. The semiconductor device of claim 13, further comprising:
an insulation layer located on a surface of the isolation layer away from the semiconductor body in the first direction and located between adjacent first electrodes,
wherein materials of the insulation structure and the insulation layer are the same.

15. The semiconductor device of claim 14, wherein the materials of the insulation structure and the insulation layer comprise boron-doped silicon nitride.

16. The semiconductor device of claim 13, wherein a material of the isolation layer comprises silicon nitride.

17. A manufacturing method of a semiconductor device, comprising:
forming an isolation layer on a side of a semiconductor body in a first direction, wherein the semiconductor body extends along the first direction;
forming a hole extending through the isolation layer to the semiconductor body;
forming a first connection structure in the hole;
etching back the first connection structure and the isolation layer to obtain a groove surrounding a part of the first connection structure away from the semiconductor body;
forming an insulation structure in the groove; and
forming a capacitor on a side of the first connection structure away from the semiconductor body.

18. The manufacturing method of claim 17, further comprising:
forming an insulation layer on a surface of the isolation layer away from the semiconductor body in the first direction,
wherein forming the capacitor on the side of the first connection structure away from the semiconductor body comprises:
forming a first electrode extending along the first direction and through the insulation layer to the first connection structure.

19. The manufacturing method of claim 18, wherein the insulation layer and the insulation structure are formed in the same thin film deposition process.

20. The manufacturing method of claim 17, further comprising:
forming a second connection structure at bottom of the hole, wherein a material of the second connection structure comprises a semiconductor,
wherein forming the first connection structure in the hole comprises:
forming the first connection structure at top of the hole, wherein forming the first connection structure at top of the hole comprises:
forming an adhesive layer on a top side wall of the hole and a top surface of the second connection structure; and
forming a body portion on an inner side of the adhesive layer, wherein a material of the body portion comprises a metal,
wherein etching back the first connection structure and the isolation layer comprises:
etching back the adhesive layer, the body portion and the isolation layer to obtain a groove surrounding a part of the body portion away from the semiconductor body.
